(19) United States
(12) Patent Application Publication
(10) Pub. No.: US 2015/0054392 A1
(43) Pub. Date: Feb. 26, 2015

(54) MOUNTING APPARATUS FOR EXPANSION CARDS

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: ZHI-MING GUO, Wuhan (CN); XIAN SHU, Wuhan (CN)

(21) Appl. No.: 14/463,860

(22) Filed: Aug. 20, 2014

(30) Foreign Application Priority Data
Aug. 21, 2013 (CN) 201310366104X

(51) Int. Cl. G06F 1/18; H05K 5/02; H05K 7/14; H05K 5/03

(52) U.S. Cl. CPC G06F 1/185; H05K 5/03; H05K 5/0221; H05K 7/1417
USPC 312/223.2; 248/226.11

(57) ABSTRACT

A mounting apparatus for securing expansion cards includes an enclosure, a cover, a pressure member, a securing member secured to the pressure member, and a stopper piece. The enclosure includes a bottom plate, and a rear plate connected to the bottom plate. The pressure member is pivotably mounted to the rear plate. The rear plate includes a rear plate body, and a mounting portion mounted to the rear plate body. The stopper piece is mounted to the mounting portion. The pressure member presses the stopper piece when rotated toward the stopper piece. The cover is mounted to the enclosure to latching block the securing member to prevent the pressure member from rotating away from the stopper piece.

### CROSS-REFERENCE TO RELATED APPLICATIONS

This application claims priority to Chinese Patent Application No. 201310366104.X filed on Aug. 21, 2013 in the China Intellectual Property Office, the contents of which are incorporated by reference herein.

### FIELD

The subject matter herein generally relates to a mounting apparatus for expansion cards.

### BACKGROUND

Usually, a mounting apparatus for an expansion card is used in a computer.

### BRIEF DESCRIPTION OF THE DRAWINGS

Implementations of the present technology will now be described, by way of example only, with reference to the attached figures.

FIG. 1 is an exploded, isometric view of an embodiment of a mounting apparatus for an expansion card.

FIG. 2 is an exploded, isometric view of a mounting assembly of the mounting apparatus of FIG. 1.

FIG. 3 is similar to FIG. 2, but viewed from a different angle.

FIG. 4 is similar to FIG. 1, but the mounting assembly is mounted to a chassis.

FIG. 5 is an enlarged view of a circled portion V of FIG. 4.

FIG. 6 is an assembled isometric view of the mounting apparatus of FIG. 1.

FIG. 7 is a cross-sectional view of the mounting apparatus of FIG. 6.

FIG. 8 is an enlarged view of a circled portion VIII of FIG. 7.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a mounting apparatus for inserting and removing an expansion card.

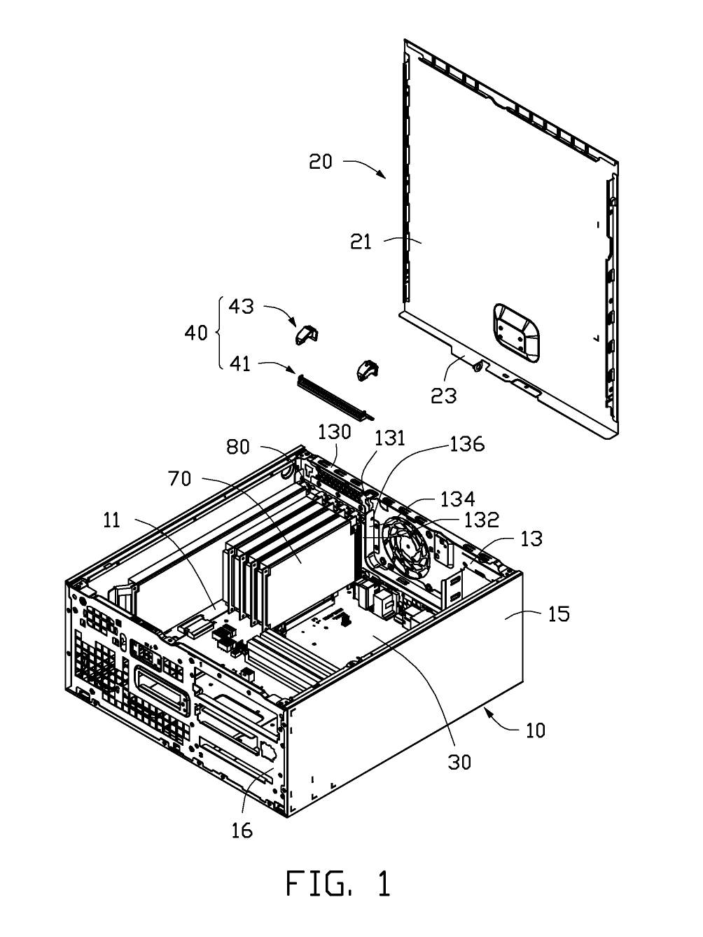

FIG. 1 illustrates an embodiment of a mounting apparatus. The mounting apparatus comprises an enclosure 10, a cover 20 mounted to the enclosure 10, a mounting assembly 40, and a stopper piece 80. The stopper piece 80 is configured to secure a plurality of expansion cards 70.

The cover 20 comprises a top portion 21, and a bent portion 23 extending substantially perpendicular from the top portion 21.

The enclosure 10 comprises a bottom plate 11, a rear plate 13 connected to the bottom plate 11, two side plates 15 connected to the bottom plate 11 and the rear plate 13, and a front plate 16 connected to the two side plates 15 and the bottom plate 11. The rear plate 13 is substantially parallel to the front plate 16. A motherboard 30 is mounted on the bottom plate 11. The rear plate 13 comprises a rear plate body 130, a mounting portion 132 mounted to the rear plate body 130, and two pivoting portions 134 mounted to the mounting portion 132. The rear plate body 130 defines two openings 131. The stopper piece 80 is mounted to the mounting portion 132. Each pivoting portion 134 defines a pivoting hole 136.

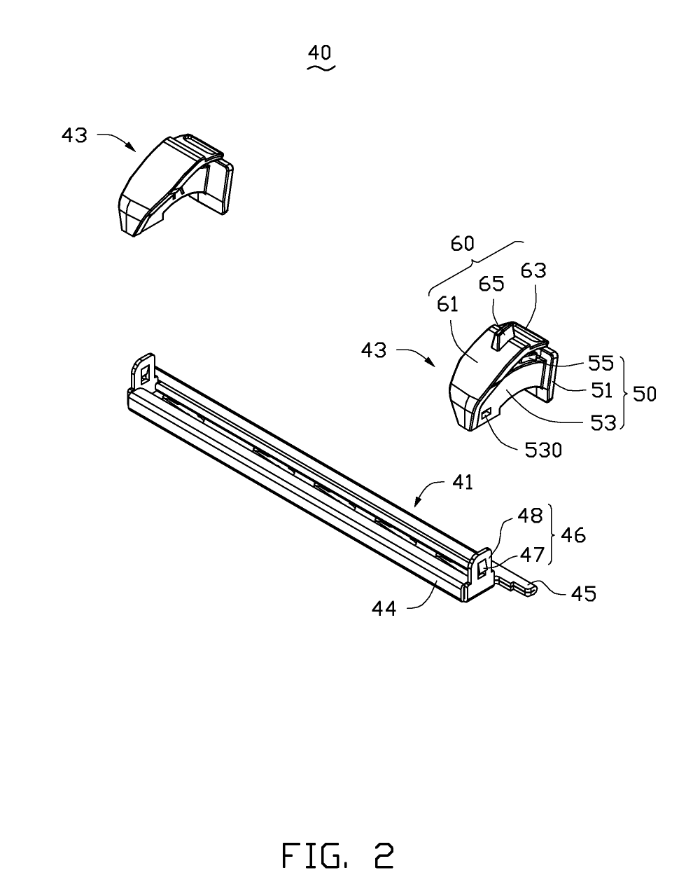

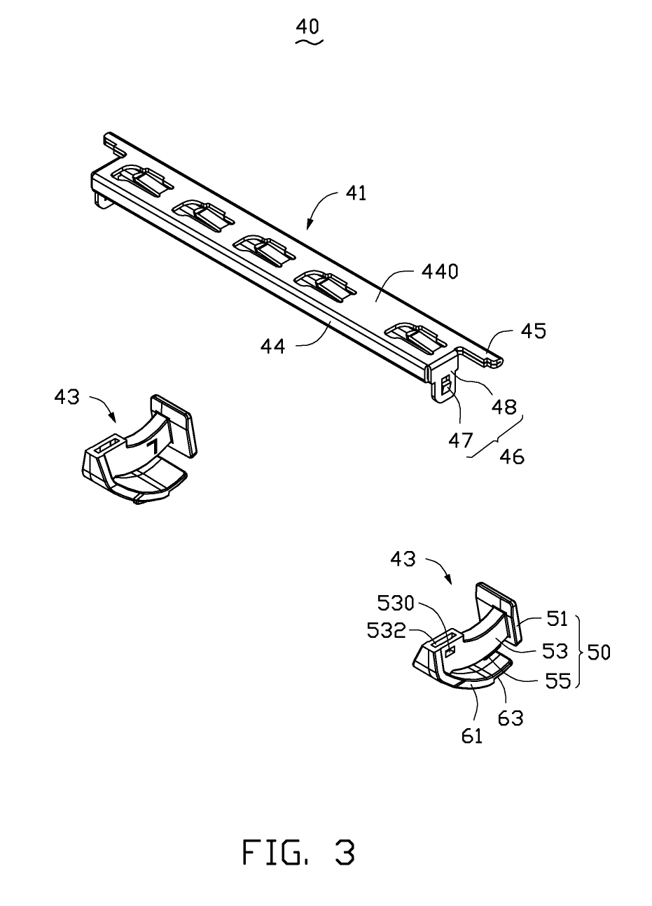

Referring to FIGS. 1-3, the mounting assembly 40 comprises a pressure member 41, and two securing members 43 mounted to the pressure member 41. The pressure member 41 comprises a weighted pressure member body 44, two extending portions 45 extending from two respective ends of one side of the pressure member body 44, and two engaging portions 46. The pressure member body 44 comprises a surface 440. The two extending portions 45 extend in substantially opposite directions. Each engaging portion 46 comprises an engaging piece 48, and a latching block 47 protruding from the engaging piece 48. The two engaging pieces 48 extend toward a substantially same direction. Each engaging piece 48 is substantially perpendicular to both the extending portions 45 and the surface 440.

Each securing member 43 comprises an operation piece 50 and an elastic piece 60. The operation piece 50 comprises a pressure portion 51, a connecting portion 53 connected to the pressure portion 51, and a stopper portion 55 connected to the connecting portion 53. The connecting portion 53 defines a first hole 532 corresponding to one engaging piece 48, and a first hole 530 corresponding to the latching block 47 and extending to the first hole 532. The elastic piece 60 comprises an elastic portion 61 connected to the connecting portion 53, and an operating portion 63 connected to the elastic portion 61. The elastic piece 60 is arcuate. One of the elastic pieces 60 further comprises a protrusion 65 protruding from the elastic portion 61. The protrusion 65 is substantially perpendicular to the elastic portion 61.

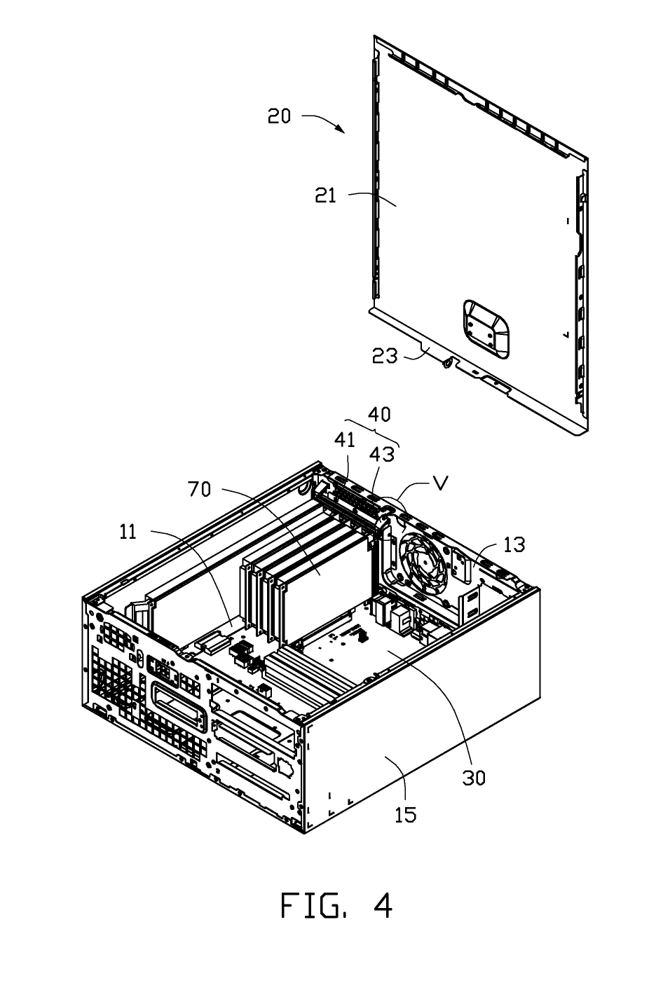

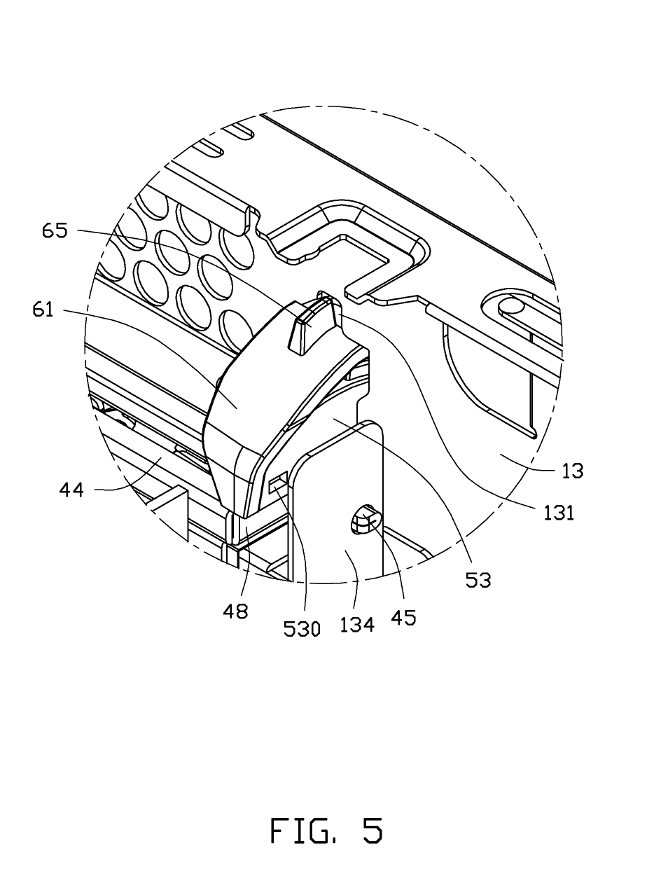

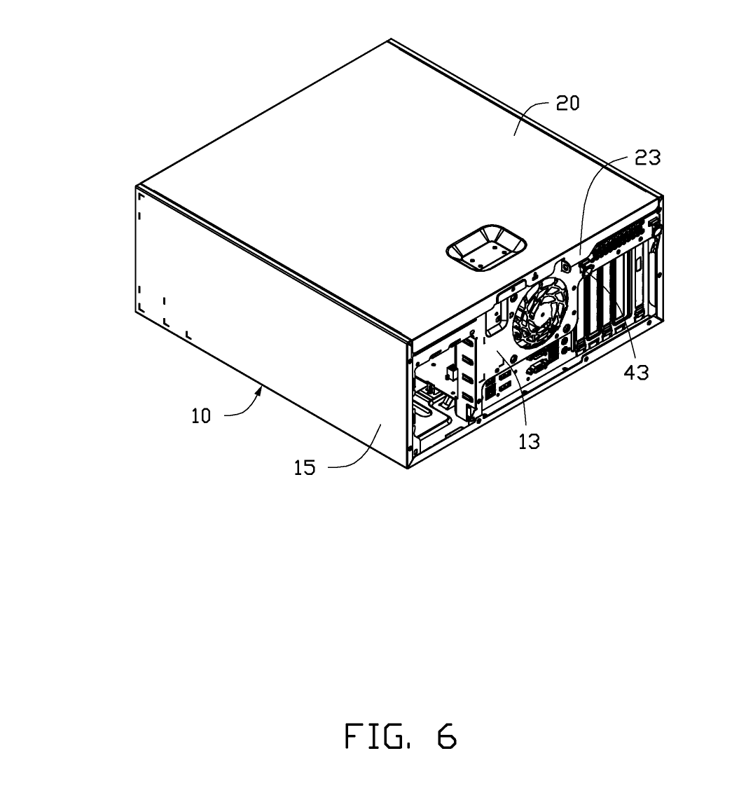

FIGS. 4-8 illustrate that in assembly, the extending portions 45 are inserted into the corresponding pivoting holes 136, thereby rotatably mounting the pressure member 41 to the mounting portion 132. In at least one embodiment, the engaging portions 46 extend through the corresponding openings 131, so that the engaging portions 46 extend outside of the enclosure 10. Each engaging piece 48 is received in the first hole 532 of the corresponding operation piece 50, and the latching block 47 is elastically deformed to latch in the second hole 530. The pressure portion 51 is pushed to rotate the pressure member 41 toward the stopper piece 80, such that the surface 440 of the weighted pressure member body 44 presses the stopper piece 80. Thus, the pressure member 41 causes the stopper piece 80 to press the expansion cards 70.

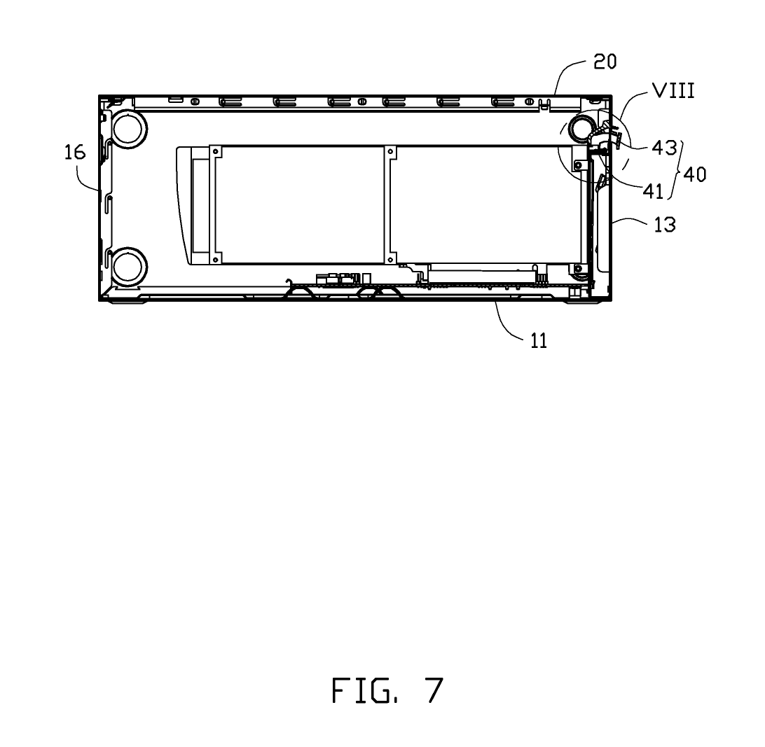

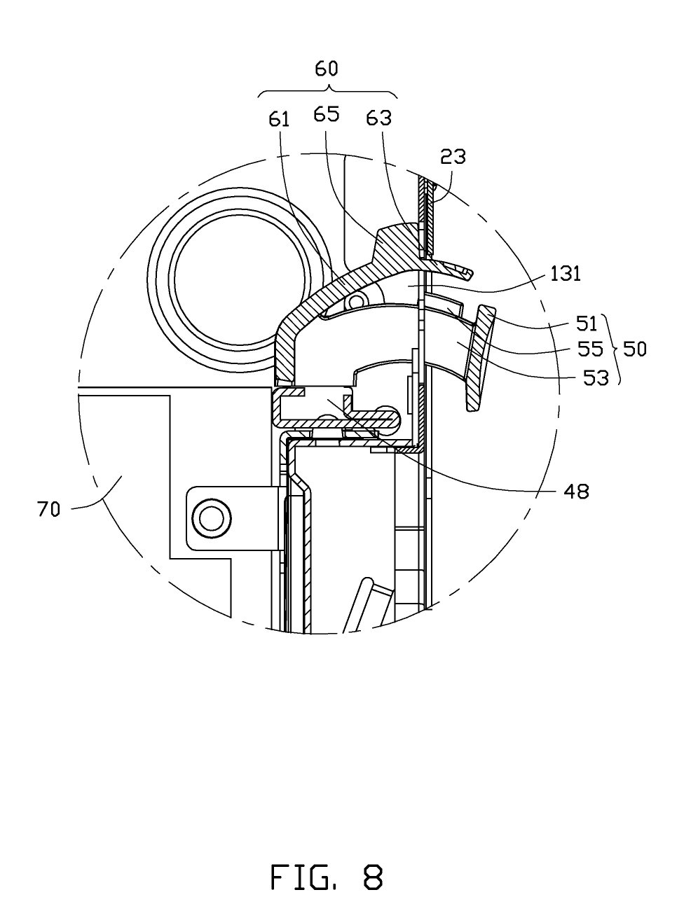

Referring to FIGS. 7-8, the protrusion 65 and each elastic portion 61 are located inside of the enclosure 10, while the operating portions 63 extend outside of the enclosure 10. The cover 20 is configured to cover the enclosure 10. The bent portion 23 corresponds to the rear plate 13 and covers a portion of the openings 131, thereby latching blocking the protrusion 65. Thus, the pressure member 41 is prevented from rotating away from the stopper piece 80.

In disassembly, the cover 20 can be removed from the enclosure 10. The operating portions 63 are pressed to rotate the pressure member 41 away from the stopper piece 80, thereby causing the engaging portions 46 to extend outside of the enclosure 10 through the openings 131. The latching blocks 47 are elastically deformed to remove the engaging portions 46 from the operating pieces 50. Thus, the extending portions 45 of the pressure member 41 can be removed from the pivoting holes 136.

It is to be understood that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure. The embodiments described herein are illustrative and are not to be construed as limiting the following claims.

What is claimed is:

1. A mounting apparatus for an expansion card comprising:
an enclosure comprising a bottom plate, and a rear plate connected to the bottom plate;
a cover;
a pressure member pivotably mounted to the rear plate;
a securing member secured to the pressure member; and
a stopper piece configured to be secured to an expansion card;
wherein the rear plate comprises a mounting portion; the stopper piece is mounted to the mounting portion; the pressure member presses the stopper piece; the cover configured to cover the enclosure to block the securing member to prevent the pressure member from rotating away from the stopper piece.

2. The mounting apparatus of claim 1, wherein the securing member comprises an operation piece and an elastic piece; the elastic piece comprises an elastic portion extending from the operation piece, and a protrusion extending from the elastic portion; the rear plate further comprising a rear plate body; the mounting portion mounted to the rear plate body; the rear plate body defines an opening; the cover prevents the pressure member from extending through the opening.

3. The mounting apparatus of claim 2, wherein the pressure member comprises a pressure member body, and an engaging portion extending from the pressure member body; the operation piece defines a second hole; the engaging portion engages in the second hole.

4. The mounting apparatus of claim 3, wherein the engaging portion comprises an engaging piece, and a latching block extending from the engaging piece; the operation piece defines a first hole; the engaging piece receives in the first hole, and the latching block receives in the second hole.

5. The mounting apparatus of claim 4, wherein the operation piece comprises a pressure portion, a connecting portion connected to the pressure portion, and a stopper portion extending from the connecting portion; the first hole and the second hole are defined in the connecting portion.

6. The mounting apparatus of claim 3, wherein the pressure member further comprises two extending portions extending from two respective ends of one side of the pressure member body; the rear plate further comprises two pivoting portions mounted to the mounting portion; and the two extending portions are pivotably mounted to the two pivoting portions.

7. The mounting apparatus of claim 6, wherein the two extending portions extend in substantially opposite directions.

8. The mounting apparatus of claim 6, wherein each pivoting portion defines a pivoting hole; the two extending portions are pivotably mounted to the corresponding pivoting holes.

9. The mounting apparatus of claim 3, wherein the pressure member body comprises a surface, the surface contacts the stopper piece.

10. The mounting apparatus of claim 9, wherein the engaging portion comprises an engaging piece extending from the pressure member body; the engaging piece is perpendicular to the surface; the operation piece defines a first hole; the engaging piece receives in the first hole.

11. A mounting apparatus for an expansion card comprising:
an enclosure comprising a bottom plate and a rear plate connected to the bottom plate;
a cover;
a pressure member pivotably mounted to the rear plate;
a securing member secured to the pressure member; and
a stopper piece;
wherein the pressure member presses the stopper piece after rotating toward the stopper piece; the cover configured to cover the enclosure to block the securing member to prevent the pressure member from rotating away from the stopper piece.

12. The mounting apparatus of claim 11, wherein the rear plate comprises a mounting portion; the stopper piece is mounted to the mounting portion; the pressure member presses the stopper piece when rotates toward the bottom plate.

13. The mounting apparatus of claim 11, wherein the rear plate further comprises a rear plate body; the mounting portion mounted to the rear plate body; the securing member comprises an operation piece and an elastic piece; the elastic piece comprises an elastic portion extending from the operation piece, and a protrusion extending from the elastic portion; the rear plate defines an opening; the cover prevents the pressure member from extending through the opening.

14. The mounting apparatus of claim 13, wherein the pressure member comprises a pressure member body, and an engaging portion extending from the pressure member body; the operation piece defines a second hole; the engaging portion engages in the second hole.

15. The mounting apparatus of claim 14, wherein the engaging portion comprises an engaging piece, and a latching block extending from the engaging piece; the operation piece defines a first hole; the engaging piece receives in the first hole, the latching block receives in the second hole.

16. The mounting apparatus of claim 15, wherein the operation piece comprises a pressure portion, a connecting portion connected to the pressure portion, and a stopper portion extending from the connecting portion; the first hole and the second hole are defined in the connecting portion.

17. The mounting apparatus of claim 14, wherein the pressure member further comprises two extending portions extending from two respective ends of one side of the pressure member body; the rear plate comprises two pivoting portions; the two extending portions are pivotably mounted to the two pivoting portions.

18. The mounting apparatus of claim 17, wherein the two extending portions extend in substantially opposite directions.

19. The mounting apparatus of claim 17, wherein each pivoting portion defines a pivoting hole; the two extending portions are pivotably mounted to the corresponding pivoting holes.

20. The mounting apparatus of claim 11, wherein the rear plate defines an opening; the cover comprises a top portion and a bent portion extending from the top portion, the top portion covers the enclosure, the bent portion prevents the pressure member from extending through the opening.
